(19) United States
(12) Patent Application Publication
(10) Pub. No.: US 2019/0346512 A1
(43) Pub. Date: Nov. 14, 2019

(54) METHOD OF DIAGNOSING LITHIUM-ION BATTERY AND DIAGNOSTIC APPARATUS FOR LITHIUM-ION BATTERY

(71) Applicant: TOYOTA JIDOSHA KABUSHIKI KAISHA, Toyota-shi (JP)

(72) Inventors: Hiroki IGUCHI, Nagoya-shi (JP); Kaoru INOUE, Hirakata-shi (JP)

(73) Assignee: TOYOTA JIDOSHA KABUSHIKI KAISHA, Toyota-shi (JP)

(21) Appl. No.: 16/391,720

(22) Filed: Apr. 23, 2019

(30) Foreign Application Priority Data
May 11, 2018 (JP) 2018-092152

(51) Int. Cl. G01R 31/387; H01M 10/0525; H01M 4/48; H01M 4/587; H01M 4/36; H01M 10/42; G01R 31/367

(52) U.S. Cl. CPC G01R 31/387; H01M 10/0525; H01M 4/483; G01R 31/367; H01M 4/364; H01M 10/4285; H01M 4/587

(57) ABSTRACT

A first information is acquired, which contains a charge capacity of a lithium-ion battery in association with an index value. The first information is used to obtain a function f(x). f(x) represents the index value as a function of the charge capacity. An extremum point of a second derivative (f″(x)) of f(x) is calculated, in which the extremum point is a minimum point of f″(x). The lithium-ion battery is diagnosed by using the charge capacity at the extremum point (xₑ). The lithium-ion battery includes a negative electrode containing at least silicon oxide and graphite. The index value is measurable from outside the lithium-ion battery. The index value is reflective of a volume of the silicon oxide and a volume of the graphite.

This nonprovisional application claims priority to Japanese Patent Application No. 2018-092152 filed on May 11, 2018, with the Japan Patent Office, the entire contents of which are hereby incorporated by reference.

### BACKGROUND

### Field

The present disclosure relates to a method of diagnosing a lithium-ion battery and a diagnostic apparatus for a lithium-ion battery.

### Description of the Background Art

International Patent Laying-Open No. WO 2015/025402 discloses a charge-discharge control apparatus for a lithium-ion battery.

### SUMMARY

As a negative electrode active material of a lithium-ion battery (which may be simply referred to as “battery” hereinafter), graphite is conventionally used. As the negative electrode active material, silicon oxide (also called “SiO” hereinafter) has been under research. SiO may have a high specific capacity compared to graphite. The “specific capacity (unit, mAh/g)” refers to capacity per unit mass. Partially replacing the graphite in a negative electrode with SiO may make it possible to obtain a battery with a high energy density.

However, SiO tends to undergo a great volume change during charge and discharge compared to graphite. After repeated charge and discharge, an electrical contact between SiO and graphite may be lost; more specifically, SiO may become isolated from the conductive network formed within the negative electrode and, thereby, may stop contributing to charge and discharge. When the amount of SiO isolated from the conductive network reaches a certain level, a sharp capacity loss may occur.

International Patent Laying-Open No. WO 2015/025402 suggests that SiO capacity and graphite capacity be estimated from the positions of peaks in a dV/dQ curve. The “dV/dQ” refers to the ratio of dV (variation in voltage (V)) to dQ (variation in capacity (Q)). The dV/dQ curve may have a peak attributable to SiO capacity. It may be because there is a difference in shape between the SiO charge-discharge curve and the graphite charge-discharge curve.

This difference in shape between the SiO charge-discharge curve and the graphite charge-discharge curve, however, may gradually decrease along with repeated charge and discharge. Therefore, after repeated charge and discharge, it may be difficult to detect a peak attributable to SiO capacity in the dV/dQ curve.

An object of the present disclosure is to provide a method of diagnosing a lithium-ion battery that includes a negative electrode containing silicon oxide and graphite.

In the following, the technical structure and the effects according to the present disclosure are described. It should be noted that part of the action mechanism according to the present disclosure is based on presumption. Therefore, the scope of claims should not be limited by whether or not the action mechanism is correct.

[1] A method of diagnosing a lithium-ion battery includes at least (A) to (C) below:

(A) acquiring a first information, the first information containing a charge capacity of the lithium-ion battery in association with an index value;

(B) calculating an extremum point of a second derivative of a function, the function being obtained by using the first information, the function representing the index value as a function of the charge capacity, the extremum point being a minimum point of the second derivative; and

(C) diagnosing the lithium-ion battery by using the charge capacity at the extremum point.

The lithium-ion battery includes a negative electrode containing at least silicon oxide and graphite. The index value is measurable from outside the lithium-ion battery. The index value is reflective of a volume of the silicon oxide and a volume of the graphite.

In the method of diagnosing a lithium-ion battery according to the present disclosure, a first information containing a charge capacity of the lithium-ion battery in association with an index value is acquired. The “charge capacity” refers to the amount of capacity to which the battery is charged at the time. For instance, a battery that is charged to a capacity of 1 Ah and then discharged by 0.5 Ah has a charge capacity of 0.5 Ah at the time.

The “index value” refers to a value measurable from outside the battery. With the index value being measurable from outside the battery, the battery may be diagnosed during use (more specifically, while the battery is on board).

FIG. 1 illustrates the method of diagnosing a lithium-ion battery according to the present disclosure.

FIG. 1 has three graphs. In the top graph, the abscissa represents charge capacity (x) and the ordinate represents the index value. f(x) is a function representing the index value as a function of x. f(x) is calculated by using the first information.

In the middle graph, the abscissa represents charge capacity (x) and the ordinate represents the rate of change in the index value (namely, the slope of f(x)). f′(x) is the first derivative of f(x). f′(x) is also calculated by using the first information.

In the bottom graph, the abscissa represents charge capacity (x) and the ordinate represents the rate of change of the slope. f″(x) is the second derivative of f(x). f″(x) is calculated by using the first information.

In the method of diagnosing a lithium-ion battery according to the present disclosure, the index value is reflective of the volume of SiO and the volume of graphite. The expression “the index value is reflective of the volume of SiO and the volume of graphite” refers to the following: the index value is monotone increasing as the volume of SiO increases; and the index value is monotone increasing as the volume of graphite increases. The term “monotone increasing” refers to monotone increasing in a broad sense (namely, monotone non-decreasing).

Each of the top graph and the middle graph where the index value is plotted against charge capacity (x) (more specifically, where the index value is expressed as a function of x) may have a first region (R1) and a second region (R2). In the first region (R1), the rate of change in the index value is relatively high (or, the slope of f(x) is relatively steep). In the second region (R2), the slope of f(x) is relatively gentle.

The first region (R1) corresponds to a low charge capacity (x) side of the graph. The first region (R1) may be reflective of SiO capacity. The electric potential for reaction of SiO and lithium ions may be higher than the electric potential for reaction of graphite and lithium ions. Therefore, in the SiO-graphite mixed system, the predominant reaction occurring in the low charge capacity (x) region may be SiO reaction. SiO may undergo a great volume change during charge and discharge compared to graphite. Therefore, the slope of f(x) may be relatively steep in the first region (R1).

The second region (R2) corresponds to a high charge capacity (x) side of the graph. The second region (R2) may be reflective of graphite capacity. The electric potential for reaction of graphite and lithium ions may be lower than the electric potential for reaction of SiO and lithium ions. Therefore, in the SiO-graphite mixed system, the predominant reaction occurring in the high charge capacity (x) region may be graphite reaction. Graphite may undergo a small volume change during charge and discharge compared to SiO. Therefore, the slope of f(x) may be relatively gentle in the second region (R2).

In the bottom graph, the rate of change of the slope is plotted. f″(x) may have its minimum point on the boundary between the first region (R1) and the second region (R2). It may be because, as shown in the middle graph, f′(x) (namely, the slope) at the boundary between the first region (R1) and the second region (R2) is decreasing.

In the method of diagnosing a lithium-ion battery according to the present disclosure, an extremum point is calculated. The extremum point is the minimum point of f″(x) (which is the rate of change of the slope). The charge capacity at the extremum point (xₑ) may serve as the border separating the first region (R1) from the second region (R2). In other words, the charge capacity at the extremum point (xₑ) may serve as the border separating SiO capacity from graphite capacity.

The charge capacity at the extremum point (xₑ) may be reflective of SiO capacity. The charge capacity at the extremum point (xₑ) may be used for battery diagnosis. The term “diagnosis (diagnosing)” used in the present disclosure encompasses at least one selected from the group consisting of “determining the battery condition”, “identifying the type of the battery condition”, and “specifying a procedure suitable for the battery condition”. For instance, the diagnostic result may specify how much capacity SiO retains at the time. For instance, the diagnostic result may predict a sharp capacity loss from SiO capacity loss.

The difference between the volume change of SiO and the volume change of graphite may be less likely to be decreased as a result of repeated charge and discharge. Likewise, the difference between the electric potential for SiO reaction and the electric potential for graphite reaction may be less likely to be decreased as a result of repeated charge and discharge. Therefore, diagnostic accuracy achieved by the method of diagnosing a lithium-ion battery according to the present disclosure may be less likely to degrade even after repeated charge and discharge.

[2] The index value may be at least one selected from the group consisting of a surface pressure of the lithium-ion battery, a thickness of the lithium-ion battery, and a volume of the lithium-ion battery.

Examples of the value that is measurable from outside the battery and reflective of the volume of SiO and the volume of graphite may include the surface pressure of the battery, the thickness of the battery, and the volume of the battery.

[3] In the method of diagnosing a lithium-ion battery according to the present disclosure, when the charge capacity at the extremum point is equal to or lower than a reference value, the diagnosing may suggest a need for changing an operating voltage range of the lithium-ion battery.

Setting a reference value (xᵣ), like in the top graph of FIG. 1, may make it possible to detect a decrease in the charge capacity at the extremum point (xₑ) (namely, “SiO capacity”) to a level equal to or lower than the reference value. When SiO capacity has decreased to a level equal to or lower than the reference value, a diagnostic result may be produced which suggests a need for changing the operating conditions of the battery so as to hamper further progress of SiO capacity loss.

For instance, a diagnostic result suggesting a need for changing the operating voltage range of the lithium-ion battery may be produced. Changing the operating voltage range of the battery may reduce the load imposed on SiO during charge and discharge. This may hamper further progress of SiO capacity loss, which in turn may enhance the battery life.

[4] The method of diagnosing a lithium-ion battery according to the present disclosure may further include (D) and (E) below:

(D) acquiring a second information regarding a usage history of the lithium-ion battery; and

(E) modifying the charge capacity at the extremum point by using the second information.

The usage history of the battery may affect degradation of a negative electrode active material. Examples of the second information regarding the usage history of the battery may include the temperature at which the battery has been used, the voltage range frequently experienced by the battery, and the duration of use of the battery. The second information may be used to modify the charge capacity at the extremum point (xₑ) (namely, “SiO capacity”). This may improve diagnostic accuracy, for example.

[5] A diagnostic apparatus for a lithium-ion battery according to the present disclosure includes at least a storage device and a computing device. The storage device is configured to store a first information, which contains a charge capacity of the lithium-ion battery in association with an index value.

The computing device is configured to perform the following processing:

(A) acquiring the first information from the storage device;

(B) calculating an extremum point of a second derivative of a function, the function being obtained by using the first information, the function representing the index value as a function of the charge capacity, the extremum point being a minimum point of the second derivative; and

(C) diagnosing the lithium-ion battery by using the charge capacity at the extremum point.

The lithium-ion battery includes a negative electrode containing at least silicon oxide and graphite. The index value is measurable from outside the lithium-ion battery. The index value is reflective of a volume of the silicon oxide and a volume of the graphite.

The diagnostic apparatus for a battery according to the present disclosure is configured to diagnose the battery by using the charge capacity at the extremum point (xₑ). The charge capacity at the extremum point (xₑ) may be reflective of SiO capacity. Therefore, the diagnostic apparatus for a battery according to the present disclosure may enable diagnosis of a battery including a negative electrode containing SiO and graphite.

[6] The index value may be at least one selected from the group consisting of a surface pressure of the lithium-ion battery, a thickness of the lithium-ion battery, and a volume of the lithium-ion battery.

[7] The computing device may be configured to provide a diagnosis that suggests a need for changing an operating voltage range of the lithium-ion battery when the charge capacity at the extremum point is equal to or lower than a reference value.

[8] The storage device may be configured to further store a second information regarding a usage history of the lithium-ion battery.

The computing device may be configured to perform the following processing:

(D) further acquiring the second information from the storage device; and

(E) modifying the charge capacity at the extremum point by using the second information.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 illustrates the method of diagnosing a lithium-ion battery according to the present disclosure.

FIG. 2 is a schematic view illustrating the structure of the lithium-ion battery.

FIG. 3 is a schematic view illustrating the structure of an electrode array.

FIG. 4 is a first conceptual view illustrating volume changes of SiO and graphite.

FIG. 5 is a second conceptual view illustrating volume changes of SiO and graphite.

FIG. 6 is a third conceptual view illustrating volume changes of SiO and graphite.

FIG. 7 is a flow chart illustrating the method of diagnosing a lithium-ion battery according to the present embodiment.

FIG. 8 illustrates a discharge curve of the lithium-ion battery.

FIG. 9 illustrates a modification factor map.

FIG. 10 is a conceptual view illustrating the structure of the diagnostic apparatus according to the present embodiment.

### DESCRIPTION OF THE PREFERRED EMBODIMENTS

In the following, embodiments according to the present disclosure (herein called “present embodiment”) are described. The description below does not limit the scope of claims.

<Lithium-Ion Battery>

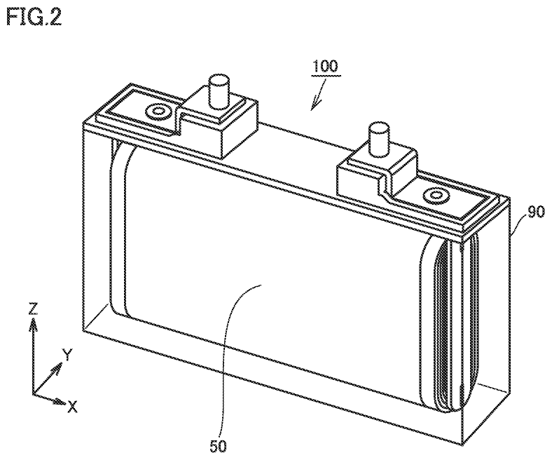

FIG. 2 is a schematic view illustrating the structure of a lithium-ion battery. A lithium-ion battery, which is to be diagnosed, is described below. A battery 100 is a prismatic battery. However, battery 100 is not limited to a prismatic battery. Battery 100 may be a cylindrical battery or a laminate-type battery, for example.

Battery 100 includes a casing 90. Casing 90 is hermetically sealed. Casing 90 may be made of metal, for example. Casing 90 accommodates an electrode array 50.

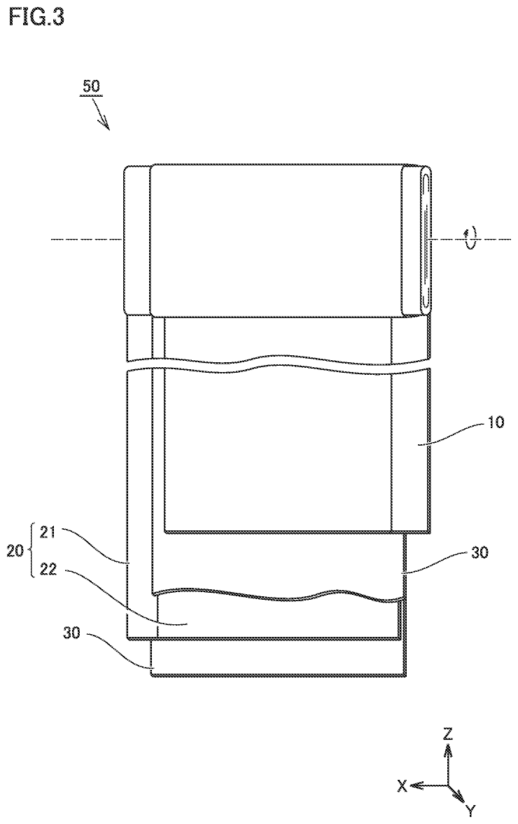

FIG. 3 is a schematic view illustrating the structure of an electrode array.

Electrode array 50 is a wound-type one. Electrode array 50 is formed by stacking a positive electrode 10, a separator 30, a negative electrode 20, and separator 30 in this order and then winding them in a spiral fashion.

However, electrode array 50 is not limited to a wound-type one. Electrode array 50 may be a stack-type one. More specifically, electrode array 50 may be formed by alternately stacking one positive electrode 10 and one negative electrode 20 and then repeating this alternate stacking process more than once. In each space between positive electrode 10 and negative electrode 20, separator 30 may be interposed.

Negative electrode 20 includes a negative electrode current collector 21 and a negative electrode composite material layer 22, for example. Negative electrode current collector 21 may be a copper foil, for example. Negative electrode composite material layer 22 is formed on a surface of negative electrode current collector 21. Negative electrode composite material layer 22 may be formed on both sides of negative electrode current collector 21.

Negative electrode composite material layer 22 contains at least a negative electrode active material. Negative electrode composite material layer 22 may contain the negative electrode active material and a binder, for example. The binder may be carboxymethylcellulose and/or styrene-butadiene rubber, for example. The mixing ratio of the negative electrode active material and the binder may be, for example: (negative electrode active material):binder=80:20 to 99.9:0.1.

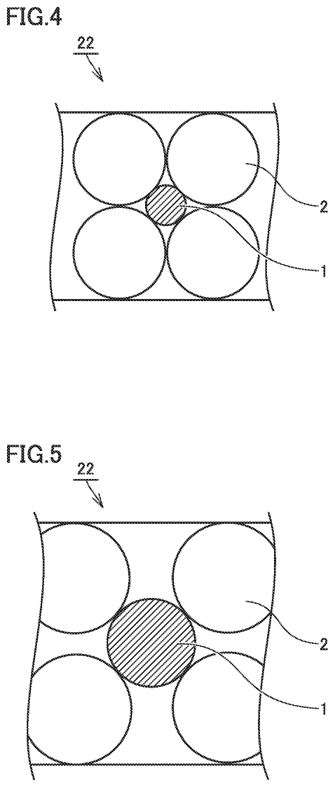

FIG. 4 is a first conceptual view illustrating volume changes of SiO and graphite.

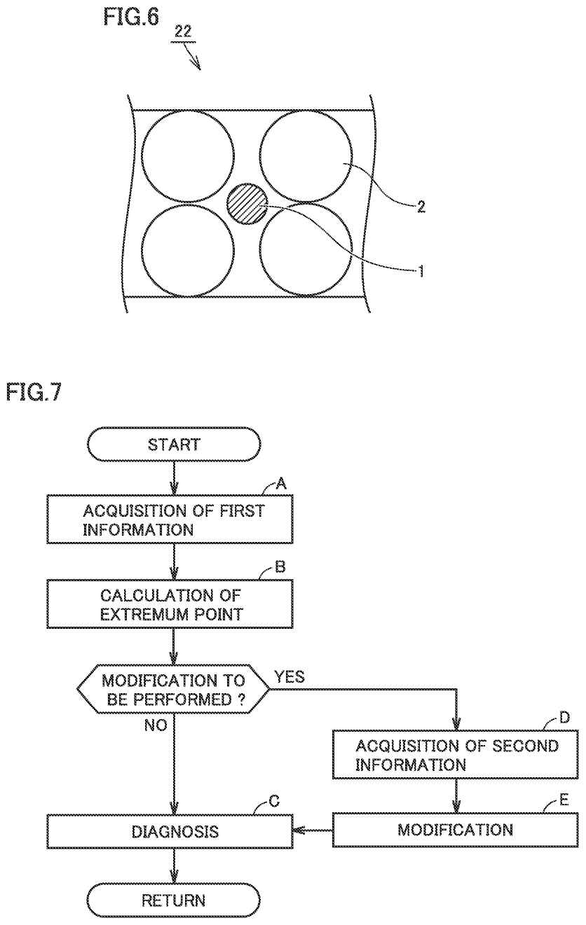

Negative electrode composite material layer 22 contains first particles 1 and second particles 2. Each of first particles 1 and second particles 2 serve as a negative electrode active material. First particles 1 contain SiO. First particles 1 may consist essentially of SiO. Second particles 2 contain graphite. Second particles 2 may consist essentially of graphite. In other words, battery 100 includes negative electrode 20 containing at least SiO and graphite. FIG. 6 illustrates negative electrode composite material layer 22 in a discharged state. In FIG. 4, first particle 1 is in electrical contact with second particle 2.

FIG. 5 is a second conceptual view illustrating volume changes of SiO and graphite.

FIG. 5 illustrates negative electrode composite material layer 22 in a charged state. Charging may cause both first particles 1 and second particles 2 to swell, which may cause negative electrode 20 to swell. When there is a limit imposed on the thickness and the volume of battery 100 (for instance, when a battery pack 150 (described below) is restrained for preventing swelling of battery 100), the swelling of negative electrode 20 may increase the surface pressure of battery 100. When battery 100 is not restrained, the swelling of negative electrode 20 may increase the thickness and the volume of battery 100.

For these reasons, at least one selected from the group consisting of the surface pressure, the thickness, and the volume of battery 100 may be used as the index value reflective of the volume of SiO and the volume of graphite. Each of the surface pressure, the thickness, and the volume of battery 100 may be measurable from outside battery 100.

The “surface pressure” in the present embodiment refers to a contact pressure between battery 100 and a sensor 201 (described below). The thickness of battery 100 refers to the dimension of battery 100 in the Y-axis direction in FIG. 2. The Y-axis direction in FIG. 2 is the stacking direction of layers of negative electrode 20. Therefore, the volume changes of SiO and graphite may be likely to be reflected to a dimensional change of battery 100 in the Y-axis direction.

First particles 1 may swell more than second particles 2 do. It may be because first particles 1 contain SiO and second particles 2 contain graphite. In FIG. 5, like in FIG. 4, first particle 1 is in electrical contact with second particle 2.

FIG. 6 is a third conceptual view illustrating volume changes of SiO and graphite.

FIG. 6 illustrates negative electrode composite material layer 22 that has shifted to a discharged state from a charged state. Discharging may cause both first particles 1 and second particles 2 to shrink, which may cause negative electrode 20 to shrink. First particles 1 may shrink more than second particles 2 do. It may be because first particles 1 contain SiO and second particles 2 contain graphite. As a result of the shrinkage, the electrical contact between first particle 1 and second particle 2 may be lost. It may be because a swelling first particle 1 pushes surrounding second particles 2 aside (see FIG. 5). The loss of electrical contact between first particle 1 and second particle 2 may make first particle 1 isolated from the conductive network formed within negative electrode 20. When the amount of first particles 1 (SiO) isolated from the conductive network reaches a certain level, a sharp capacity loss may occur.

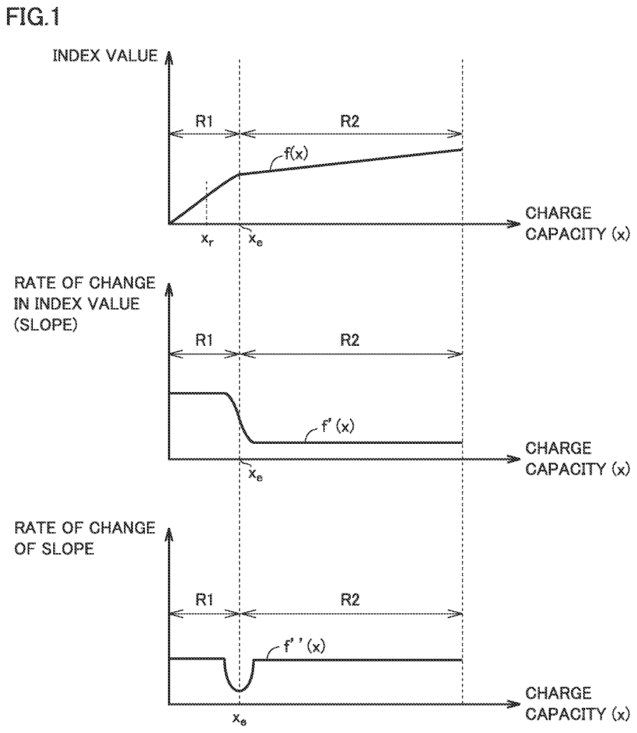

It should be noted that FIGS. 4 to 6 do not indicate, for convenience, the difference between the timing of swelling of first particles 1 (SiO) and that of second particles 2 (graphite) or the difference between the timing of shrinkage of first particles 1 (SiO) and that of second particles 2 (graphite). In an actual battery, however, there may be a difference between the charge capacity range with a marked swelling of first particles 1 (SiO) and that with a marked swelling of second particles 2 (graphite); and also between the charge capacity range with a marked shrinkage of first particles 1 (SiO) and that with a marked shrinkage of second particles 2 (graphite). These differences may be responsible for the presence of the first region (R1) and the second region (R2) in f(x) (see FIG. 1).

The SiO according to the present embodiment refers to a compound containing silicon (Si) and oxygen (O). The Si/O ratio of the SiO according to the present embodiment may be any conventionally known ratio. The SiO may have the following compositional formula: SiOₖ (where k satisfies 0<k<2), for example. k may satisfy 0.5≤k≤1.5, for example. The SiO may contain, for example, a trace amount of an impurity element and the like that are inevitably entrapped during production. The SiO may contain, for example, a trace amount of an additive element and the like that are intentionally added.

The graphite according to the present embodiment refers to a carbon material having a graphite crystal structure or a crystal structure similar to a graphite crystal structure. Therefore, the graphite according to the present embodiment may also include soft carbon and hard carbon, for example. More specifically, negative electrode 20 may contain at least one selected from the group consisting of graphite, soft carbon, and hard carbon.

The SiO/graphite mixing ratio in negative electrode 20 may be, for example:

SiO:graphite=1:99 to 99:1 (mass ratio).
The SiO/graphite mixing ratio may be, for example:
SiO:graphite=1:99 to 20:80 (mass ratio).
The SiO/graphite mixing ratio may be, for example:
SiO:graphite=5:95 to 15:85 (mass ratio).

As long as negative electrode 20 includes SiO and graphite, other components of battery 100 (such as positive electrode 10, separator 30, and an electrolyte) are not particularly limited. These other components may be any conventionally known components that may be included in a lithium-ion battery.

Positive electrode 10 may include, for example, lithium nickel cobalt manganese oxide (such as LiNi_{1/3}Co_{1/3}Mn_{1/3}O₂) as a positive electrode active material. Separator 30 may be a porous polyethylene film, for example.

The electrolyte is a lithium-ion conductor. The electrolyte may be an electrolyte solution, for example. The electrolyte solution contains a solvent and a lithium salt. The solvent may have, for example, the following composition: “(ethylene carbonate)/(dimethyl carbonate)/(ethyl methyl carbonate)=3/4/3 (volume ratio)”. The lithium salt may be LiPF₆, for example. The lithium salt concentration may be about 0.5 to 2 mol/l, for example.

The electrolyte may be a gelled electrolyte. The electrolyte may be a solid electrolyte. In other words, battery 100 may be an all-solid-state battery. The all-solid-state battery may include no separator 30.

<Method of Diagnosing Lithium-Ion Battery>

Next, the method of diagnosing a lithium-ion battery according to the present embodiment is described. Hereinafter, the method of diagnosing a lithium-ion battery according to the present embodiment may be simply referred to as “the diagnosis method according to the present embodiment”.

FIG. 7 is a flow chart illustrating the method of diagnosing a lithium-ion battery according to the present embodiment.

The method of diagnosing a battery according to the present embodiment includes at least “(A) acquisition of a first information”, “(B) calculation of an extremum point”, and “(C) diagnosis”. The method of diagnosing a battery according to the present embodiment may further include “(D) acquisition of a second information” and “(E) modification”.

<<(A) Acquisition of First Information>>

The method of diagnosing a battery according to the present embodiment includes acquiring a first information containing a charge capacity of battery 100 in association with an index value.

The index value is a value measurable from outside battery 100. The index value may be measured with sensor 201 (described below). With the index value being measurable from outside battery 100, battery 100 may be diagnosed while on board.

The index value is reflective of the volume of SiO and the volume of graphite. As described above, the index value may be the surface pressure of battery 100, the thickness of battery 100, and/or the volume of battery 100, for example. One type of the index value may be used alone. Two or more types of the index value may be used in combination. In other words, the index value may be at least one selected from the group consisting of the surface pressure of battery 100, the thickness of battery 100, and the volume of battery 100, for example.

The charge capacity refers to the amount of capacity to which battery 100 is charged at the time. The first information may be acquired by, for example, measuring the index value (such as the surface pressure of battery 100) during charge and discharge. The index value may be measured while charge or discharge is not proceeding. The first information may be acquired while, for instance, battery 100 is on a vehicle (namely, while battery 100 is on board). Examples of the vehicle on which battery 100 is mounted may include electric vehicles (EVs), hybrid vehicles (HVs), and plug-in hybrid vehicles (PHVs).

<<(B) Calculation of Extremum Point>>

The method of diagnosing a battery according to the present embodiment includes calculating an extremum point of a second derivative (f″(x)) of a function f(x). f(x) is obtained by using the first information. f(x) represents the index value as a function of the charge capacity. The extremum point is a minimum point of f″(x) (see FIG. 1).

The charge capacity at the extremum point (xₑ) may be on the boundary between the first region (R1) reflective of SiO capacity and the second region (R2) reflective of graphite capacity. The first region (R1) and the second region (R2) may be visualized (or represented by a graph) as in FIG. 1, for example. Hereinafter, the “charge capacity at the extremum point (xₑ)” is also simply called “charge capacity (xₑ)”.

The charge capacity (xₑ) calculated by using the first information may be used as it is, without modification, for diagnosis. In such a configuration (namely, when the determination in the flow chart of FIG. 7 is “NO (no modification)”), “(B) calculation of an extremum point” is followed by “(C) diagnosis”.

The charge capacity (xₑ) may be modified by using a second information (usage history) described below. The charge capacity after modification (xₑ′) may be used for diagnosis. In such a configuration (namely, when the determination in the flow chart of FIG. 7 is “YES (modification to be performed)”), “(B) calculation of an extremum point” is followed by “(D) acquisition of a second information”.

<<(C) Diagnosis>>

The method of diagnosing a battery according to the present embodiment includes diagnosing battery 100 by using the charge capacity at the extremum point (xₑ). For instance, the charge capacity (xₑ) may be compared with a reference value (xᵣ) (see FIG. 1). For instance, when the charge capacity (xₑ) is equal to or lower than the reference value (xᵣ), the diagnosis may suggest that battery 100 is in a condition that is defined in advance.

The reference value (xᵣ) may be set on the basis of, for example, results of a charge-discharge cycle test performed on battery 100. An example process for the setting is as follows: battery 100 is subjected to a charge-discharge cycle test while the charge capacity (xₑ) is calculated during every cycle or the like; the charge capacity (xₑ) during a specific cycle in the charge-discharge cycle test during which a sharp capacity loss has occurred is acquired; the charge capacity (xₑ) during that specific cycle with a sharp capacity loss, for example, is multiplied by a predetermined coefficient; and thus the reference value (xᵣ) may be calculated. For instance, the reference value (xᵣ) may be about 1.1 to 1.5 times the charge capacity (xₑ) during the specific cycle with a sharp capacity loss. A plurality of reference values may be set in a stepwise manner.

When the charge capacity (xₑ) is equal to or lower than the reference value (xᵣ), the diagnosis may predict a sharp capacity loss in battery 100. When the charge capacity (xₑ) is higher than the reference value (xᵣ), the diagnosis may suggest that battery 100 is in a good condition.

The diagnostic result may specify a procedure that is necessary for maintaining a good condition of the vehicle and/or the like on which battery 100 is mounted. For instance, when the charge capacity (xₑ) is equal to or lower than the reference value (xᵣ), the diagnosis may suggest a need for replacing battery 100.

The diagnostic result may specify a procedure that is necessary for, for instance, prolonging the service life of battery 100. For instance, when the charge capacity (xₑ) is equal to or lower than the reference value (xᵣ), the diagnosis may suggest a need for changing the operating conditions of battery 100. Examples of the operating conditions that may be changed include the operating voltage range of battery 100, the temperature at which battery 100 is placed (for example, cooling conditions), and the restraining pressure applied on battery 100 in battery pack 150. In brief, when the charge capacity (xₑ) is equal to or lower than the reference value (xᵣ), the diagnosis may suggest a need for changing the operating voltage range of battery 100.

(Change in Operating Voltage Range)

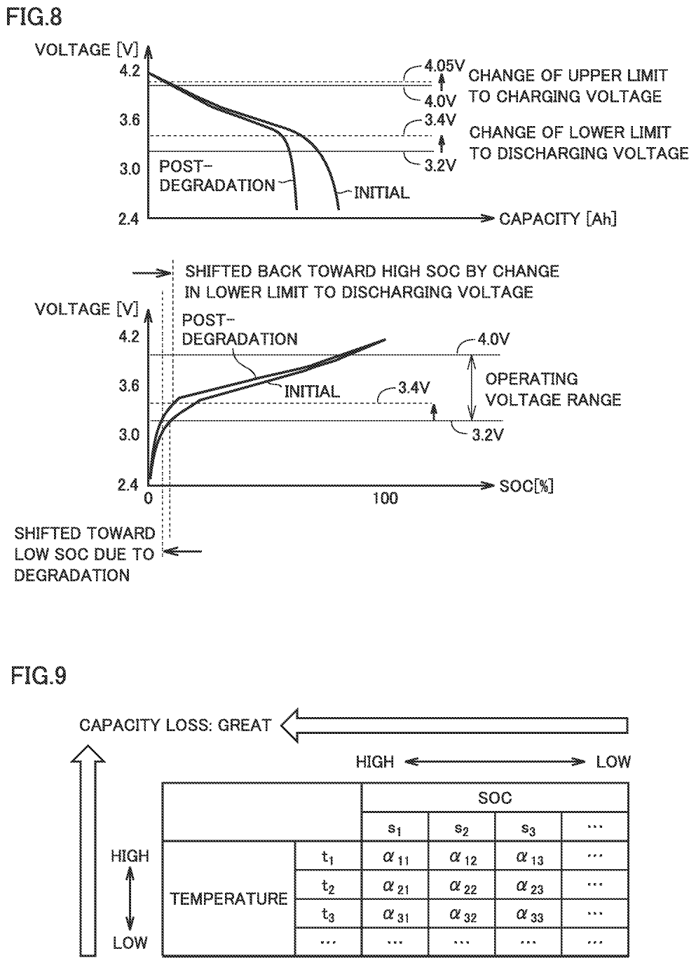

FIG. 8 illustrates a discharge curve of the lithium-ion battery.

FIG. 8 includes two graphs. In the upper graph, the abscissa represents discharged capacity and the ordinate represents battery voltage. In this graph, an “initial” discharge curve and a “post-degradation” discharge curve are plotted. The “post-degradation” state refers to a state after repeated charge and discharge, for instance. Battery 100 that has been used and degraded may have a decreased discharged capacity as well as a change in the shape of the discharge curve.

The lower graph is different from the upper graph in that the abscissa represents SOC (state of charge). In the lower graph, the operating voltage range is hypothetically fixed to the range from 3.2 V to 4.0 V. With the operating voltage range of battery 100 being fixed, the SOC range during use may shift toward low SOC as the degradation of battery 100 proceeds. This shift may be attributed to the change in the shape of the discharge curve.

The electric potential for SiO reaction may be higher than the electric potential for graphite reaction. Therefore, the predominant reaction occurring in the low SOC region may be SiO reaction and the predominant reaction occurring in the high SOC region may be graphite reaction. As the SOC range during use shifts toward low SOC, the load imposed on SiO during charge and discharge may increase. As the load on SiO increases in this way, SiO capacity loss may be accelerated.

For instance, the lower limit to the discharging voltage may be raised. This may shift the SOC range during use back toward high SOC and may reduce the load on SiO. In FIG. 8, an aspect involving raising the lower limit to the discharging voltage from 3.2 V to 3.4 V is illustrated.

However, raising the lower limit to the discharging voltage narrows the operating voltage range, potentially decreasing available capacity. This may be counterbalanced by raising the upper limit to the charging voltage. In FIG. 8, an aspect involving raising the upper limit to the charging voltage from 4.0 V to 4.05 V is illustrated. This may mitigate a decrease in available capacity.

Shifting the entire SOC range during use toward high SOC may increase the average volume of SiO and the average volume of graphite during charge and discharge. This may, for instance, restore the electrical contact between SiO and graphite.

<<(D) Acquisition of Second Information>>

The method of diagnosing a battery according to the present embodiment may further include acquiring a second information regarding the usage history of battery 100.

The second information may be acquired while, for instance, battery 100 is on a vehicle. The second information may be accumulated in, for example, a storage device 250 (described below). The usage history may be a temperature history and an SOC history, for example.

<<(E) Modification>>

The method of diagnosing a battery according to the present embodiment may further include modifying the charge capacity at the extremum point (xₑ) by using the second information.

For instance, a modification factor (α) may be derived from the usage history. The modification factor may be a value greater than 0 and smaller than 1, for example. By multiplying the charge capacity (xₑ) by the modification factor (α), a charge capacity after modification (xₑ′) may be calculated. Using the charge capacity after modification (xₑ′) for diagnosis may improve diagnostic accuracy, for example.

For instance, the charge capacity after modification (xₑ′) may be compared with the reference value (xᵣ). For instance, when the charge capacity after modification (xₑ′) is equal to or lower than the reference value (xᵣ), the diagnosis may predict a sharp capacity loss in battery 100. For instance, when the charge capacity after modification (xₑ′) is equal to or lower than the reference value (xᵣ), the diagnosis may suggest a need for replacing battery 100. For instance, when the charge capacity after modification (xₑ′) is equal to or lower than the reference value (xᵣ), the diagnosis may suggest a need for changing the operating conditions of battery 100. For instance, when the charge capacity after modification (xₑ′) is equal to or lower than the reference value (xᵣ), the diagnosis may suggest a need for changing the operating voltage range of battery 100.

(Modification Factor Map)

FIG. 9 illustrates a modification factor map.

The present embodiment may use a modification factor map, for example.

FIG. 9 illustrates a modification factor map regarding the temperature history and the SOC history. For instance, when the temperature during use is “t₁” and the SOC during use is “s₂”, modification factor “α₁₂” is derived. The higher the temperature during use is, the greater the capacity loss may be. Therefore, the modification factor map may be configured in such a way that the modification factor decreases as the temperature increases. The higher the SOC during use is, the greater the capacity loss may be. Therefore, the modification factor map may be configured in such a way that the modification factor decreases as the SOC increases.

<Diagnostic Apparatus for Lithium-Ion Battery>

Next, a diagnostic apparatus for a lithium-ion battery according to the present embodiment is described. Hereinafter, the diagnostic apparatus for a lithium-ion battery according to the present embodiment may be simply referred to as “the diagnostic apparatus according to the present embodiment”.

The diagnostic apparatus according to the present embodiment may be mounted on, for example, a vehicle on which battery 100 is mounted. The diagnostic apparatus according to the present embodiment may be mounted on, for example, a stationary power storage system on which battery 100 is mounted. The diagnostic apparatus according to the present embodiment may be used to diagnose battery 100 that has been collected in a regular inspection and/or the like.

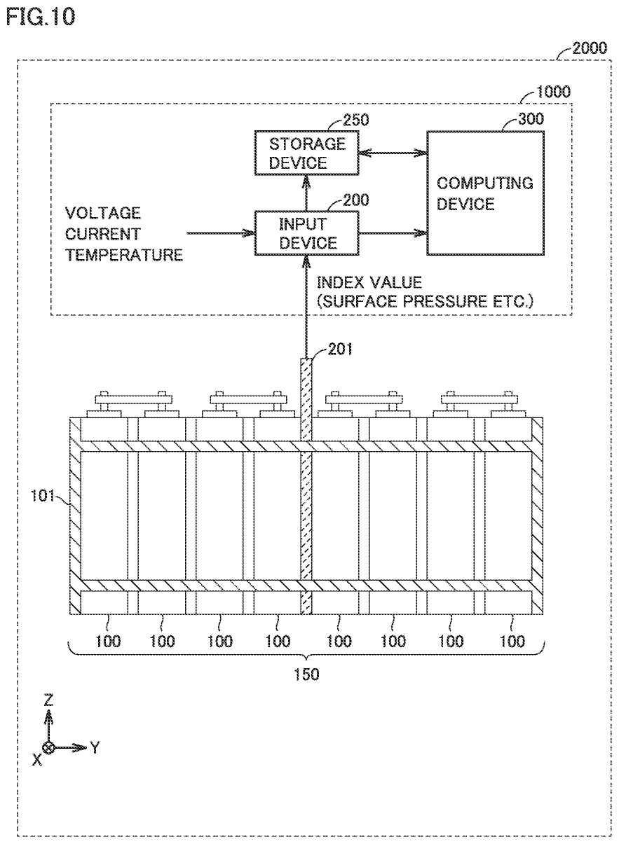

FIG. 10 is a conceptual view illustrating the structure of the diagnostic apparatus according to the present embodiment.

A diagnostic apparatus 1000 includes an input device 200, storage device 250, and a computing device 300. In other words, diagnostic apparatus 1000 includes at least storage device 250 and computing device 300. Diagnostic apparatus 1000 may further include, for example, an output device that outputs diagnostic results. The devices may be connected to each other via a cable and/or the like. The devices may be connected to each other via a wireless network and/or the like.

For instance, diagnostic apparatus 1000 and battery 100 may constitute a battery system 2000. In other words, the present embodiment may also provide battery system 2000. Battery system 2000 includes at least diagnostic apparatus 1000 and battery 100. Battery 100 includes negative electrode 20 containing at least SiO and graphite. Battery system 2000 may include one battery 100. Battery system 2000 may include a plurality of batteries 100. Battery system 2000 may include battery pack 150.

<<Input Device>>

Input device 200 is connected to sensor 201. Into input device 200, information from sensor 201 is input. Sensor 201 measures the index value from outside battery 100. The index value is reflective of the volume of SiO and the volume of graphite. The index value may be at least one selected from the group consisting of the surface pressure of battery 100, the thickness of battery 100, and the volume of battery 100.

As sensor 201, a sensor suitable for the index value is selected. In the aspect illustrated in FIG. 10, sensor 201 is a surface pressure sensor; in other words, the index value is the surface pressure of battery 100. In FIG. 10, a plurality of batteries 100 constitute battery pack 150. The batteries 100 are restrained with the use of a restraining tool 101 (such as a band). Sensor 201 is interposed between two batteries 100.

In the configuration of battery pack 150, the index value of one battery 100 may be measured or the index value of two or more batteries 100 may be measured. In other words, in the configuration of battery pack 150, the index value of at least one battery 100 is simply required to be measured. One sensor 201 may be used alone. Two or more sensors 201 may be used.

In addition to the information from sensor 201 (namely, the index value), other types of information may further be input into input device 200. For example, information indicating conditions of battery 100 during use (such as voltage, current, and temperature) may be input into input device 200 from other sensors (not shown).

<<Storage Device>>

Storage device 250 is connected to computing device 300 and input device 200. Storage device 250 is configured to store the first information containing the charge capacity of battery 100 in association with the index value.

Storage device 250 may be configured to further store the second information regarding the usage history of battery 100. For instance, information indicating conditions of battery 100 during use that has been input into input device 200 may be accumulated in storage device 250 and, thereby, the second information regarding the usage history of battery 100 may be formed in storage device 250. Storage device 250 may store the modification factor map.

<<Computing Device>>

Computing device 300 is connected to input device 200 and storage device 250. For instance, computing device 300 may acquire information regarding the charge capacity of battery 100 (such as charge current, charge duration, discharge current, and discharge duration) from input device 200. Computing device 300 may calculate the charge capacity at the time from the information regarding the charge capacity. Computing device 300 may acquire the index value at the time (value detected with sensor 201) from input device 200. Computing device 300 may associate the charge capacity at the time with the index value at the time and, thereby, form the first information. Computing device 300 may have the first information stored in storage device 250.

The charge capacity at the time and the index value at the time may be directly, without computing device 300 being involved, input from input device 200 into storage device 250 and stored in storage device 250.

Computing device 300 may be configured to perform the actions specified in the flow chart of FIG. 7 at an external command. Computing device 300 may be configured to perform the actions specified in the flow chart of FIG. 7 automatically in response to, for instance, a predetermined condition having been satisfied (for instance, after a lapse of a predetermined time from previous diagnosis).

Computing device 300 is configured to perform the following processing according to the flow chart of FIG. 7:

(A) acquiring the first information from storage device 250;

(B) calculating an extremum point of a second derivative (f″(x)) of a function f(x), f(x) being obtained by using the first information, f(x) representing the index value as a function of the charge capacity, the extremum point being a minimum point of f″(x) (see FIG. 1); and

(C) diagnosing battery 100 by using the charge capacity at the extremum point (xₑ).

The diagnostic result produced by computing device 300 may be output on the output device (not shown) and/or the like. By this, the diagnostic result may be presented to a user. The diagnostic result produced by computing device 300 may be transferred to, for example, a control device (not shown), which controls charge and discharge of battery 100.

For instance, computing device 300 may be configured to compare the charge capacity (xₑ) with the reference value (xᵣ) (see FIG. 1). For instance, computing device 300 may be configured to provide a diagnosis that predicts a sharp capacity loss in battery 100 when the charge capacity (xₑ) is equal to or lower than the reference value (xᵣ). For instance, computing device 300 may be configured to provide a diagnosis that suggests a need for replacing battery 100 when the charge capacity (xₑ) is equal to or lower than the reference value (xᵣ).

For instance, computing device 300 may be configured to provide a diagnosis that suggests a need for changing the operating conditions of battery 100 when the charge capacity (xₑ) is equal to or lower than the reference value (xᵣ). For instance, computing device 300 may be configured to provide a diagnosis that suggests a need for changing the operating voltage range of battery 100 when the charge capacity (xₑ) is equal to or lower than the reference value (xᵣ).

In the configuration of battery pack 150, computing device 300 may provide a diagnosis that suggests a need for changing the operating conditions of one or some of batteries 100, or computing device 300 may provide a diagnosis that suggests a need for changing the operating conditions of all batteries 100.

Computing device 300 may be configured to perform the following processing:

(D) further acquiring the second information from storage device 250; and

(E) modifying the charge capacity at the extremum point (xₑ) by using the second information.

For instance, computing device 300 may acquire the second information and the modification factor map from storage device 250. For instance, computing device 300 may modify the charge capacity (xₑ) by using the second information and the modification factor map. By this, the charge capacity after modification (xₑ′) may be calculated. Computing device 300 may be configured to diagnose battery 100 by using the charge capacity after modification (xₑ′).

For instance, computing device 300 may be configured to compare the charge capacity after modification (xₑ′) with the reference value (xᵣ). For instance, computing device 300 may be configured to provide a diagnosis that predicts a sharp capacity loss in battery 100 when the charge capacity after modification (xₑ′) is equal to or lower than the reference value (xᵣ). For instance, computing device 300 may be configured to provide a diagnosis that suggests a need for replacing battery 100 when the charge capacity after modification (xₑ′) is equal to or lower than the reference value (xᵣ).

For instance, computing device 300 may be configured to provide a diagnosis that suggests a need for changing the operating conditions of battery 100 when the charge capacity after modification (xₑ′) is equal to or lower than the reference value (xᵣ). For instance, computing device 300 may be configured to provide a diagnosis that suggests a need for changing the operating voltage range of battery 100 when the charge capacity after modification (xₑ′) is equal to or lower than the reference value (xᵣ).

The embodiments and examples disclosed herein are illustrative and non-restrictive in any respect. The technical scope indicated by the claims is intended to include any modifications within the scope and meaning equivalent to the terms of the claims.

What is claimed is:

1. A method of diagnosing a lithium-ion battery, the method comprising at least:
acquiring a first information, the first information containing a charge capacity of the lithium-ion battery in association with an index value;
calculating an extremum point of a second derivative of a function, the function being obtained by using the first information, the function representing the index value as a function of the charge capacity, the extremum point being a minimum point of the second derivative; and
diagnosing the lithium-ion battery by using the charge capacity at the extremum point,
the lithium-ion battery including a negative electrode, the negative electrode containing at least silicon oxide and graphite,
the index value being measurable from outside the lithium-ion battery,
the index value being reflective of a volume of the silicon oxide and a volume of the graphite.

2. The method of diagnosing a lithium-ion battery according to claim 1, wherein
the index value is at least one selected from the group consisting of a surface pressure of the lithium-ion battery, a thickness of the lithium-ion battery, and a volume of the lithium-ion battery.

3. The method of diagnosing a lithium-ion battery according to claim 1, wherein
when the charge capacity at the extremum point is equal to or lower than a reference value, the diagnosing suggests a need for changing an operating voltage range of the lithium-ion battery.

4. The method of diagnosing a lithium-ion battery according to claim 1, the method further comprising:
acquiring a second information regarding a usage history of the lithium-ion battery; and
modifying the charge capacity at the extremum point by using the second information.

5. A diagnostic apparatus for a lithium-ion battery, the diagnostic apparatus comprising at least:
a storage device; and
a computing device,
the storage device being configured to store a first information, the first information containing a charge capacity of the lithium-ion battery in association with an index value,
the computing device being configured to:
acquire the first information from the storage device;
calculate an extremum point of a second derivative of a function, the function being obtained by using the first information, the function representing the index value as a function of the charge capacity, the extremum point being a minimum point of the second derivative; and
diagnose the lithium-ion battery by using the charge capacity at the extremum point,
the lithium-ion battery including a negative electrode, the negative electrode containing at least silicon oxide and graphite,
the index value being measurable from outside the lithium-ion battery,
the index value being reflective of a volume of the silicon oxide and a volume of the graphite.

6. The diagnostic apparatus for a lithium-ion battery according to claim 5, wherein
the index value is at least one selected from the group consisting of a surface pressure of the lithium-ion battery, a thickness of the lithium-ion battery, and a volume of the lithium-ion battery.

7. The diagnostic apparatus for a lithium-ion battery according to claim 5, wherein
the computing device is configured to provide a diagnosis that suggests a need for changing an operating voltage range of the lithium-ion battery when the charge capacity at the extremum point is equal to or lower than a reference value.

8. The diagnostic apparatus for a lithium-ion battery according to claim 5, wherein
the storage device is configured to further store a second information regarding a usage history of the lithium-ion battery, and
the computing device is configured to:
further acquire the second information from the storage device; and
modify the charge capacity at the extremum point by using the second information.
